(19) United States
(12) Patent Application Publication
(10) Pub. No.: US 2005/0190507 A1
(43) Pub. Date: Sep. 1, 2005

(54) Magnetic field sensor

(76) Inventors: Peter Littlewood, Cambridge (GB); Meera Parish, Cambridge (GB)

Correspondence Address: MORGAN & FINNEGAN, L.L.P., 3 WORLD FINANCIAL CENTER, NEW YORK, NY, 10281-2101, US

(21) Appl. No.: 10/791,090

(22) Filed: Mar. 1, 2004

(51) Int. Cl. G11B 5/33; G11B 5/127; G01R 33/02

(52) U.S. Cl. 360/313; 257/421

(57) ABSTRACT

A magnetic field sensing structure is described that uses magnetoresistance as a signal. The structure includes an inhomogeneous network of interconnected semiconducting elements which may be of various shapes. By tuning or selecting physical properties of the elements, the overall magnetoresistive response may be adjusted to be large and substantially linear over a range of magnetic fields. Such sensing structures may be used, for example, in hard-disk read-heads. Other embodiments may find application in low or high field sensing, with some being of particular interest where thermal stability is of importance.

The invention relates to magnetic field sensors and particularly although not exclusively to low-field sensors. Some embodiments also relate to high-field sensors.

Recently, an anomalously large magnetoresistance was observed in two doped silver chalcogenides, Ag_{2+δ}Se and Ag_{2+δ}Te, where the resistance displayed a positive linear dependence on the magnetic field over the temperature range 4.5K to 300K, without any signs of saturation at fields as high as 60T. These characteristics make the compounds ideally suited for the development of magnetoresistive devices such as magnetic field sensors, but the origin of the linear magnetoresistance still remains unclear.

The silver chalcogenides are narrow-gap semiconductors, so conventional theories predict that the magnetoresistance should saturate at large fields, unlike what is observed. Moreover, the silver chalcogenides possess no magnetic moments, therefore the magnetoresistance cannot be spin-mediated like the colossal magnetoresistance of the manganites. Polycrystalline metals may also exhibit a linear magnetoresistance, but this behaviour requires the presence of open Fermi surfaces which is not the case here.

Currently, the only proposed explanation for the silver chalcogenide phenomenon is “quantum magnetoresistance” of Abrikosov. However, doped silver chalcogenides are granular materials and a linear magnetoresistance has also been observed in metals with surface imperfections and in disordered indium antimonide. Therefore, an alternative hypothesis is that the linear magnetoresistance of the silver chalcogenides results from large spatial fluctuations in the conductivity of the material, due to the inhomogeneous distribution of silver ions.

U.S. Pat. No. 5,965,283 describes a semi-conductor structure with an inclusion of more conducting material that exhibits enhanced magnetoresistance.

U.S. Pat. No. 6,353,317 describes a magnetic field sensor comprising special semi-conductor/metal nano-composite structures produced using island lithography.

WO01/21414 also discloses sensor structures comprising a combination of semiconducting and conducting materials.

While these prior art magnetic field sensors may show an increased magnetoresistance, the response is highly non-linear and saturates at high fields. Production of small-scale sensors also requires expensive, specialist technology (see e.g. U.S. Pat. No. 6,353,317).

### SUMMARY OF THE INVENTION

Based on the idea that the desirable properties of silver chalcogenides result from spatial fluctuations in the conductivity of the material, the invention provides a magnetic field sensor which allows fine control of the magnetoresistive response and is easy to manufacture. Typical embodiments are expected to show a large, substantially linear, magnetoresistive response.

According to the present invention there is provided a magnetic field sensing structure comprising a first electrode and a second electrode, the first and second electrodes being electrically coupled via a network comprising a plurality of discrete semiconducting elements providing a plurality of possible current paths between the electrodes.

It is expected that commercial embodiments of the invention may achieve a ten percent effect at 100 gauss, that is of the same order as current read heads for hard disk drives, but with much reduced manufacturing costs. Furthermore, a sensors according to embodiments of the invention typically show a linear, non-saturating response and would thus also be suitable for high field applications, or applications where a graded or quantitative output is necessary.

Many of the preferred embodiments of the invention show good thermal stability, and thus have applications in high-temperature fields or in fields in which fluctuating temperatures are to be expected.

Finally, the absence of any metallic parts in some embodiments of the invention allow the sensor to be used in conditions where ferromagnetic materials must be excluded, e.g. high field applications such as in medical scanners.

### BRIEF DESCRIPTION OF THE DRAWINGS

The invention may be more readily understood by one skilled in the art with reference to the description of several specific embodiments in conjunction with the accompanying drawings, wherein like elements are designated by identical reference numerals throughout the drawings, in which:

FIG. 1 is a schematic illustration of a first embodiment;

FIG. 2a and b are schematic illustrations of different implementations of the first embodiments;

FIG. 3a to e are schematic illustrations of a second embodiment;

FIG. 4 is a schematic illustration of a third embodiment;

FIG. 5 is schematic illustration of a sensor or read head embodying a sensing structure according to the first, second or third embodiments; and

FIG. 6 is a schematic illustration of a fourth embodiment of the invention.

### DETAILED DESCRIPTION OF THE INVENTION

A sensor incorporating a manufactured sensing structure as described in the several embodiments below provides a low cost, high sensitivity magnetic field sensor, which is particularly suitable to detect low intensity fields. However, given the potential for a sensor which does not saturate at high magnetic fields, such a sensor would be equally suitable for high field applications.

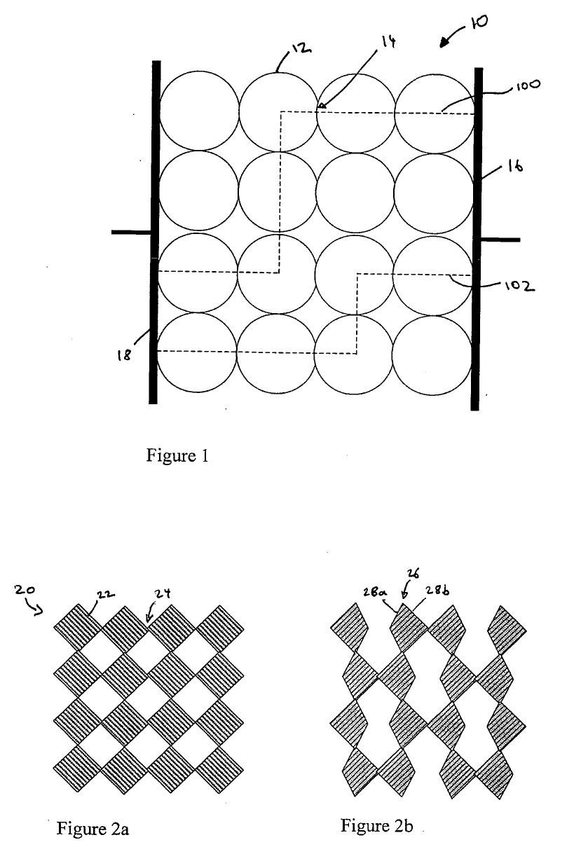

A first embodiment, shown in FIG. 1, comprises a rectangular 4×4 sensing structure or array 10 of discrete disk-shaped semiconductor elements 12, which are disposed on a substrate (not shown). The elements 12 overlap to a small extent to form connections 14 between elements 12. Electrodes 16, 18 apply a voltage across the array. These electrodes are of metal or some other substance which forms a good ohmic contact with the elements 12. In the preferred embodiment, the electrodes connect to each of the disks on opposing sides of the array, as shown, but in an alternative arrangement (not shown) the electrodes may connect only to some but not all of the opposing elements.

In use, a potential difference is established between the electrodes 16, 18 and the overall resistance of the structure determined in any convenient way, for example by measuring the current that flows for a given potential difference and calculating the resistance using Ohm's law. One of the electrodes may, but need not, be grounded. In calculating the resistance, it is not essential to use the value of the potential difference which has been established between the electrodes. Instead, separate voltage probes (not shown) applied to two or more individual elements may be used; such an arrangement avoids the problem of contact potentials.

In this embodiment, the applicant has discovered, surprisingly, that the measured resistance across the array varies substantially linearly with the strength of a magnetic field applied to the array, and furthermore that this linearity does not appear to saturate even when extremely high magnetic fields are applied. Further numerical experimentation has shown that the magnetoresistive response does not saturate when the number of columns between the electrodes is even, but that the response does saturate when the number is odd.

It is believed that the resistance changes with applied field as a result of the current taking a variety of differing paths between the electrodes. At low applied fields, for example, the current might preferentially take a first path 100 as shown in FIG. 1, but at high fields this might become less advantageous because of differing individual element responses to the applied field, and a second path 102 may then be preferred. The preferred path may change depending upon how (if at all) each of the individual elements reacts in the presence of the field, and in particular the extent to which each element manifests a Hall effect voltage.

It will be understood that, in alternative embodiments, the elements 12 need not be disk-shaped, nor does their interconnectivity have to be as shown in FIG. 1. The elements may be identical or alternatively they may differ in at least one electrical property such as resistance or mean free path.

If disk-shaped elements are arranged on a rectangular grid, each element will of course have four contacts with adjacent elements. Such an embodiment could, of course, equally well have different numbers of elements along perpendicular edges (e.g. 4×3) as well as the equal numbers (4×4) shown in FIG. 1. On the other hand, if disk shaped elements are arranged on a hexagonal grid, each element will then have six contacts with adjacent elements. Alternatively by using different shapes for the elements, different numbers of connections can be achieved.

In some embodiments the number of elements involved may potentially be quite small. So, for example, where a rectangular grid arrangement is employed, grids as small as 1×2, 2×2 or 1×3 may be envisaged (the first figure in each case representing the number of rows between the electrodes).

For example, using diamond-shaped elements 22 and 26 as shown in FIGS. 2a and b, differing connectivities can be achieved. The elements 22 in FIG. 2a use a diamond shape with four equal sides, and provides an arrangement in which each element 22 has four connections 24 with adjacent elements. By using diamond-shaped elements 26 that have two short sides 28a and two long sides 28b a connection scheme with three connections per element can be established in a rectangular grid as shown in FIG. 2b . This is achieved by an arrangement where the long sides 28b point in alternating directions from one row of the grid to the next.

Of course, many different connection schemes can be established using different shapes of the elements 12. Moreover, the elements are not restricted to being the same size or shape and thus any desirable pattern of connectivity is achievable by selecting the shapes of the elements accordingly. Similarly, it is not essential for the elements to be disposed in a regular grid.

The elements are formed on the substrate using standard semiconductor technology, such as lithography. The size of the elements is preferably less than 1 μm, for example 0.1 μm. Smaller feature sizes of 10 to 20 nm could be achieved using self-assembling quantum dot arrays. However, the size of each element is preferably larger than the mean free parts of charge carriers.

Any suitable semiconductor material, preferably of high carrier mobility, can be used, for example of GaAs, InSb, AlAs, InGaAs, InAs, InSb, InGaNAs, GaN, Ge, SiGe or Si. In fact, the sensing structure could even be formed by constructing the elements from a metal layer, although metal may be less desirable material due to its small Hall effect.

Each individual element may be homogenous in its physical properties, or alternatively each element could, in itself, be inhomogeneous. Similarly, the physical properties of the elements may differ one from another or alternatively the properties of each of the elements may be substantially the same. In either case, one of the particular benefits of the invention lies in the ability to tune the magnetoresistive response during manufacture by selecting appropriate physical properties of the elements in order to achieve a particular desired magnetoresistive response. Appropriate physical properties to be selected include (but are not limited to) material, resistance, carrier mobility, size, shape and so on.

To this end, the thickness (i.e. the dimension at the elements 12 perpendicular to the substrate), radius or other geometric factor of each element can be tuned or selected by using different lithographic designs, or the carrier mobility of the elements can be tuned by doping of the elements. Each of these manipulations will affect the magnetoresistance of the individual elements and can thus be used to tune the overall response curve. Furthermore, the magnetoresistive response can be tuned by selecting the number of elements and their interconnection topology.

By increasing the number of elements in the sensing structure 10, linearity at low fields of the magnetoresistance response is typically increased. In addition, if a large number of elements (e.g. a grid of 20×20 elements) is used with a distribution over the carrier mobility of the elements, the characteristic field (at which the response switches from a quadratic response at low fields to a linear response at higher fields) can be tuned by varying the properties of the distribution.

If the spread of the mobility distribution (e.g. a Gaussian distribution) is larger than the average of the mobility distribution, simulations have shown that the characteristic field is given by the inverse of the spread of the mobility distribution rather than by the average mobility. “Spread”, here, may refer to any width characteristic of the distribution e.g. the standard deviation or any multiplicative factor thereof, or to the difference between the greatest value of an element within the network and the least. Thus, by doping the elements such that average mobility is close to ( ) (note that p-type doping gives positive mobility) and the spread of the mobility distribution is large, linear behaviour can be expected down to very low fields.

As discussed above, the magnetoresistive response of the sensing structure 10 can be tuned by selecting characteristics of the elements 12, and by selecting the number, arrangement and connection patterns of elements 12. An infinite number of arrangements and connection patterns is clearly possible, subject only to the constraint that there must exist current paths between the electrodes 16 and 18 that allow current components that are both parallel and perpendicular to the electrodes. There must, thus, be at least two elements in parallel, but implementations with four elements, between 5 to 100 elements, or even with more than 100 elements can also be envisaged.

In other arrangements (not shown) there may be more than two electrodes 16, 18 and/or these may be positioned other than as shown in FIG. 1. For example, four electrodes may be provided, along the respective edges of the structure; this allows more flexibility in the application of different voltages to the device.

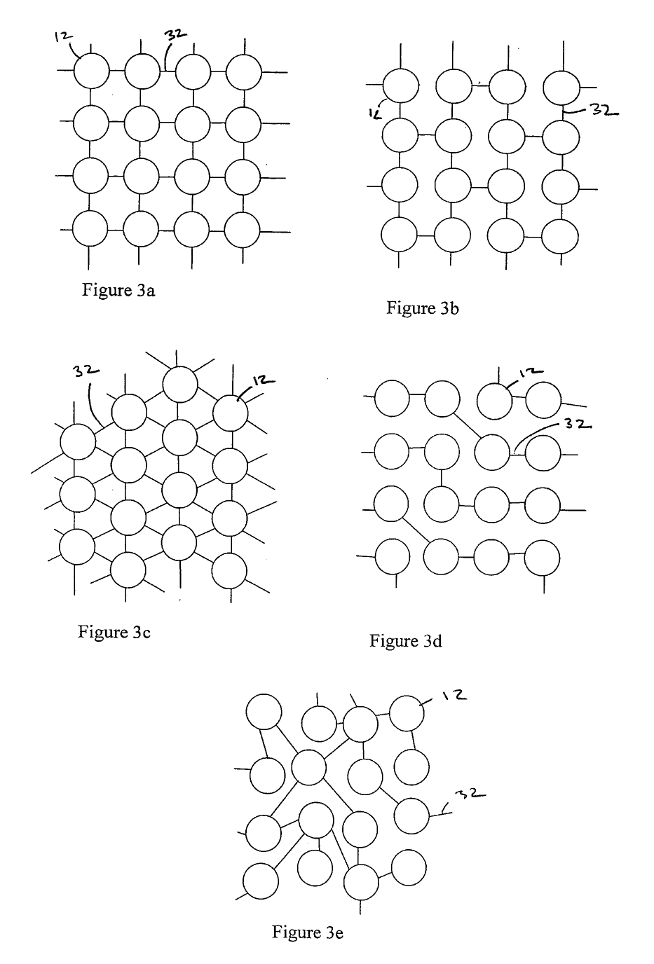

FIGS. 3a to 3e show a variety of second embodiments. In these embodiments, the elements 12 do not overlap, but instead form separate islands. The elements are thus spaced apart and connected by bridges 32 (as shown in FIG. 3a ) of conducting material. These may consist of for example wires or tracks of metal or of some suitably doped semiconductor materials.

The second embodiment is, in its functioning to a large extent equivalent to the first embodiment and the same considerations regarding the tuning of the magnetoresistive response still apply. However, the looser arrangement of elements 12 and the independence of the connection scheme from the geometrical shape of the elements allows for a more flexible design of connection patterns. FIGS. 3a to c show connection patterns with respectively 4, 3 and 6 connections per element; these could of course also be achieved by overlapping elements that are disk shaped or diamond shaped. However, the connection pattern in FIG. 3d (two connections per element) and the connection pattern in FIG. 3e (variable number of connections per element) would be impossible to achieve with overlapping elements unless different element shapes are used or different element spacings provided.

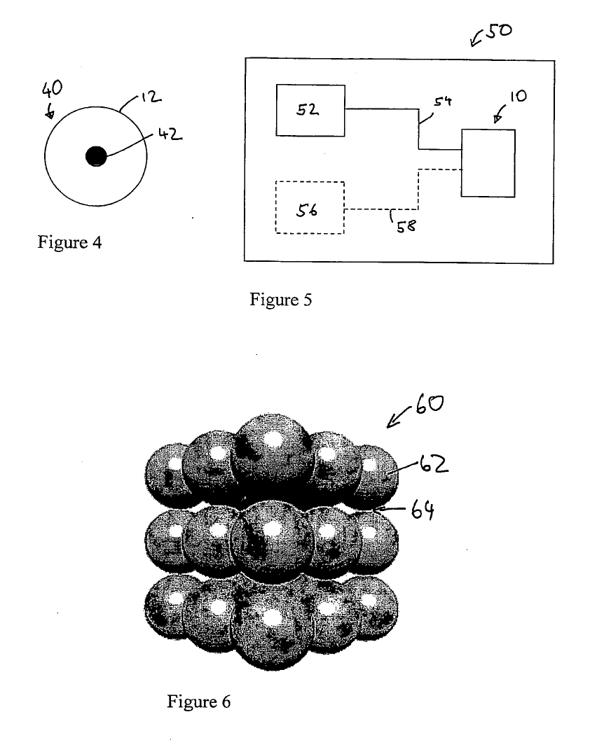

In a third embodiment, a controllable element 40 (shown in FIG. 4) is used in conjunction with the structures of the first and second embodiments. The element 40 comprises an element 12, as described above, and, additionally a control 42 (for example a control electrode) associated with the element 12. The control 42 may allow electrons to be injected or extracted from element 12 thus providing real-time tuning of the carrier density of the element 40.

By providing a structure that has one or more controllable elements 40 of this type (or even providing a structure that is wholly made up of such elements), and by altering the physical properties of the element(s) in real time, one can control and adjust the overall magnetoresistive response of the sensing structure while the sensor is in use. Instead of, or in addition to, tuning the element electron densities, as discussed above, the controls 42 could be used to adjust carrier mobility and/or to apply a variable voltage to individual elements.

It will be understood, of course, that the respective controls 42 of the elements 40 may be addressed in any conventional manner, for example by means of a metallic or non-metallic control grid (not shown) which overlies or otherwise connects to the individual elements. In a preferred arrangement, the controls 42 comprise individually addressable gating structures which apply controllable gate voltages. Such structures may be created by any convenient means—for example using a surface metal pad with a separately controlled voltage bias across an oxide or insulating barrier. Alternatively, the controls 42 could comprise optically-gated structures. Other possibilities include epitaxially grown structures—by MBE, CVD, MOVPD etc., two-dimensional electron gas structures, MOS capacitor structures and MIS structures.

A sensor incorporating a sensing structure according to the first or second embodiment is shown in FIG. 5. The sensor 50 comprises a measuring arrangement 52 connected by lead 54 to the electrodes 16 and 18 (not shown in FIG. 5) of sensing structure 10. If a sensing structure according to a third embodiment is used, the sensor 50 further comprises a mobility controller 56 which is connected by leads 58 to a control grid (not shown) which is coupled to the mobility control connections 42 of the elements of the sensing structure 10. Mobility controller 56 is used to tune the magnetoresistive response of the sensor in real time and, potentially, in use by injecting or extracting charges (eg electrons or holes) from the elements 12 of the structure 10. A sensor as described above may be used in a magnetic read-head, for example in a hard-disk drive.

The first, second and third embodiments all provide two-dimensional sensing structures. In certain circumstances, for example when measuring the longitudinal component of a magnetic field is desirable, a three-dimensional sensing structure may be provided. In the fourth embodiment of the invention, such a sensing structure is provided by means of a three-dimensional stacking 60 of three-dimensional elements 62, as shown in FIG. 6. Such elements may be in the shape of a sphere or octahedron and the stacking may be for example, a simple cubic stacking. FIG. 6 shows a simple cubic stacking 60 in which elements 62 are overlapping in six locations, thus providing six contacts per element. Of course, as with the two-dimensional embodiments, other element shapes, configurations and connection topologies may be envisaged.

It is envisaged that the invention, in its broadest form, may include any one or more of the novel features of any of the specific embodiments described above or shown in the drawings. It is specifically to be understood that any of the features of one embodiment or variant may be combined with any compatible feature of any other embodiment or variant.

From the foregoing, it will be apparent that novel sensing structures for magnetic fields have been disclosed and that changes as to the precise arrangements, shapes, details and connectivities of the component parts may be made by those having ordinary skill in the art without departing from the spirit of the invention or the scope thereof as set out in the claims which follow.

1. A magnetic field sensing structure comprising a first electrode and a second electrode, the first and second electrodes being electrically coupled via a network comprising a plurality of discrete semiconducting elements providing a plurality of possible current paths between the electrodes.

2. A magnetic field sensing structure as claimed in claim 1 in which the elements are disposed in a regular array.

3. A magnetic field sensing structure as claimed in claim 2 in which the array defines a rectangular grid.

4. A magnetic field sensing structure as claimed in claim 2 in which the array defines a hexagonal grid.

5. A magnetic field sensing structure as claimed in claim 1 in which the elements are disposed in an irregular array.

6. A magnetic field sensing structure as claimed in claim 1 in which elements within the network are electrically coupled to three other elements.

7. A magnetic field sensing structure as claimed in claim 1 in which elements within the network are electrically coupled to four other elements.

8. A magnetic field sensing structure as claimed in claim 1 in which elements within the network are electrically coupled to at least three other elements, the number of electrical couplings varying between different elements within the network.

9. A magnetic fields sensing structure as claimed in claim 1 in which some first elements within the network are electrically coupled to three other elements, and in which some second elements within the network are electrically coupled to four other elements.

10. A magnetic field sensing structure as claimed in claim 2 in which the array has first and second edge rows of elements defining first and second opposing edges and in which the electrodes are electrically coupled to the elements of the said edge rows.

11. A magnetic field sensing structure as claimed in claim 1 in which the elements are disk-shaped.

12. A magnetic field sensing structure as claimed in claim 1 in which the elements are diamond-shaped.

13. A magnetic field sensing structure as claimed in claim 1 in which the dimensions of the elements are smaller than 1 μm.

14. A magnetic field sensing structure as claimed in claim 1 in which the dimensions of the elements are approximately 0.1 μm.

15. A magnetic field sensing structure as claimed in claim 1 in which the dimensions of the elements are larger than the mean free path of charge carriers within the elements.

16. A magnetic field sensing structure as claimed in claim 1 in which the elements are formed of any one or more of GaAs, InSb, AlAs, InGaAs, InAs, InSb, InGaNAs, GaN, Ge, SiGe or Si.

17. A magnetic field sensing structure as claimed in claim 1 in which the carrier mobility differs between different elements.

18. A magnetic field sensing structure as claimed in claim 17 in which the individual element carrier mobilities define a distribution having a mean and a spread, the spread being greater than the mean.

19. A magnetic field sensing structure as claimed in claim 17 in which the individual element carrier mobilities define a distribution which is substantially Gaussian.

20. A magnetic field sensing structure as claimed in claim 1 in which a physical element dimension differs between different elements.

21. A magnetic field sensing structure as claimed in claim 1 in which the semiconducting elements are interconnected by means of conductive connections.

22. A magnetic field sensing structure as claimed in claim 21 in which the conductive connections comprise metal wires or pathways.

23. A magnetic field sensing structure as claimed in claim 1 in which the semiconducting elements are interconnected by direct contact, one with the other.

24. A magnetic field sensing structure as claimed in claim 1 in which the semiconducting elements are disposed on a substrate.

25. A magnetic field sensing structure as claimed in claim 24 in which the elements are applied to the substrate by lithography.

26. A magnetic field sensing structure as claimed in claim 1 in which the semiconducting elements are disposed on a substrate and are interconnected by virtue of a partial overlap, one with the other.

27. A magnetic field sensing structure as claimed in claim 1 in which an electrical property of at least one of the elements is controllable in real time.

28. A magnetic field sensing structure as claimed in claim 27 in which each element includes a controllable gating structure.

29. A magnetic field sensing structure as claimed in claim 1 in which the network extends in three dimensions.

30. A magnetic field sensing structure as claimed in claim 29 in which the elements are spherical or octahedral.

31. A magnetic field sensing structure as claimed in claim 29 in which the elements define a simple cubic array.

32. A magnetic field sensor comprising a sensing structure as claimed in claim 1 and a resistance-measuring device for measuring the electrical resistance between the electrodes at a given magnetic field strength.

33. A magnetic read-head including a sensing structure as claimed in claim 1.

34. A read-head as claimed in claim 32 comprising a hard disk or a tape read-head.

35. A magnetic field sensor comprising a sensing structure as claimed in claim 28, a resistance-measuring device for measuring the electrical resistance between the electrodes at a given magnetic field strength, and a mobility controller for tuning the magnetorestorative response of the sensing structure.

36. A magnetic field sensing structure as claimed in claim 27 in which the said electrical property is carrier density.

37. A magnetic field sensing structure as claimed in claim 27 in which the said electrical property is a carrier mobility.

38. A magnetic field sensing structure as claimed in claim 28 in which the gating structure is electronically-gated.

39. A magnetic field sensing structure as claimed in claim 28 in which the gating structure is optically-gated.

40. A magnetic field sensing structure as claimed in claim 1 in which the said elements have substantially identical electrical properties.

41. A magnetic field sensing structure as claimed in claim 1 in which the electrical properties of the said element differ.
